(19) United States
(12) Patent Application Publication
(10) Pub. No.: US 2024/0106192 A1
(43) Pub. Date: Mar. 28, 2024

(54) Programmable Transmit/Receive Pixel Array and Applications

(71) Applicant: Apple Inc., Cupertino, CA (US)

(72) Inventors: Fei Tan, Sunnyvale, CA (US); Keith Lyon, San Jose, CA (US); Tong Chen, Fremont, CA (US); Chin Han Lin, Cupertino, CA (US); Xiaofeng Fan, San Jose, CA (US); Arnaud Laflaquiere, Grenoble (FR)

(21) Appl. No.: 17/951,410

(22) Filed: Sep. 23, 2022

(51) Int. Cl. H01S 5/026; G01S 7/481; G02B 7/28; G03B 13/20; G03B 13/36; H01L 31/12; H01S 5/042; H01S 5/42

(52) U.S. Cl. CPC H01S 5/0262; G01S 7/4812; G02B 7/287; G03B 13/20; G03B 13/36; H01L 31/125; H01S 5/042; H01S 5/423

(57) ABSTRACT

Disclosed herein are electronic devices that include arrays of dual function light transmit and receive pixels. The pixels of such arrays include a photodetector (PD) structure and a vertical-cavity, surface-emitting laser (VCSEL) diode, both formed in a common stack of epitaxial semiconductor layers. The pixels of the array may be configured by a controller or processor to function either as a light emitter by biasing the VCSEL diode, or as a light detector or receiver by a different bias applied to the PD structure, and this functionality may be altered in time. The array of dual function pixels may be positioned interior to an optical display of an electronic device, in some cases to provide depth sensing or autofocus. The array of pixels may be registered with a camera of an electronic device, such as to provide depth sensing or autofocus.

### FIELD

The present disclosure generally relates to optical sensors having an array of dual function pixels operable to transmit and receive light, and electronic devices that include such pixel arrays. Such optical sensors may be used, for example, in conjunction with displays and cameras of such electronic devices.

### BACKGROUND

Electronic devices, such as cell phones, digital cameras, tablet or laptop computers, and the like, often include optical sensors. Such optical sensors may emit light, such as laser light, or may receive incoming light from an environment exterior to the electronic device, or both. Optical sensors that are capable of both emitting and receiving light are sometimes referred to as active optical sensors.

Optical sensors may be part of an imaging system of the electronic device, or may be used in conjunction with a display panel of the electronic device, such as for range finding or other ambient light level detection, among other applications.

### SUMMARY

This summary is provided to introduce a selection of concepts in a simplified form that are further described below in the Detailed Description section. This summary is not intended to identify key features or essential features of the claimed subject matter, nor is it intended to be used as an aid in determining the scope of the claimed subject matter.

Disclosed herein are electronic devices that contain programmable active optical sensors. The programmable active optical sensors may include pixel arrays that include dual function light transmit and receive pixels, or hereinafter, ‘dual function pixels,’ or just ‘pixels’ if clear from the context. The pixels of such a pixel array are formed in a common set of epitaxial layers, and each pixel includes a respective vertical cavity surface-emitting laser (VCSEL) and a respective photodiode (PD). The electronic devices also include respective controllers electrically connected to each respective VCSEL and each respective PD. The controller is operable to apply a first electrical bias at a first time to configure a pixel as a light transmitter only, and to apply a second electrical bias at a second time to configure the pixel as a light receiver only.

The PDs of the pixels may be formed in a first subset of epitaxial layers of the common set of epitaxial layers, adjacent to a light input-output (LIO) layer of the programmable active optical sensor. The VCSEL diodes of the pixels may be formed in a second subset of epitaxial layers of the common set of epitaxial layers, opposite to the LIO layer of the programmable active optical sensor.

Also disclosed herein is an electronic device that includes a display component positioned adjacent to a light transmissive surface of the electronic device, an array of dual function pixels formed in a common set of epitaxial layers, and a controller. Each pixel of the array of dual function pixels includes a respective VCSEL diode and a respective PD. The array of pixels is positioned proximate to the display component, opposite to the light transmissive surface. The controller is operably linked to the respective VCSEL diode and the respective PD of each pixel of the array of pixels. When a first electrical bias is applied to a first pixel, the respective VCSEL diode of the first pixel is operable to emit light and the respective PD of the first pixel is unbiased. When a second electrical bias is applied to the first pixel, the respective PD of the first pixel is biased to detect light and the respective VCSEL diode of the first pixel is unbiased. The controller is operable to determine signal-to-noise ratios (SNRs) of at least some of the VCSEL diodes and at least some of the PDs, and configure different pixels to operate as VCSEL diodes or PDs at least partly in response to the determined SNRs.

The present disclosure also describes an electronic device that includes a camera, a controller, and an array of dual function pixels positioned adjacent to a light transmissive surface of the electronic device. The array of pixels is formed in a common set of epitaxial layers, with each pixel in the array of pixels including a respective VCSEL diode and a respective PD. The controller is electrically connected to each respective VCSEL diode and each respective PD of each pixel of the array of pixels, and is operable to apply a first electrical bias at a first time to configure the respective VCSEL diode of a first pixel to emit light, and to apply a second electrical bias at a second time to configure the respective PD of the first pixel to detect light. The controller may further be operable to associate a selected subset of pixels of the array of pixels with a section of a field of view of the camera.

### BRIEF DESCRIPTION OF THE DRAWINGS

The disclosure will be readily understood by the following detailed description in conjunction with the accompanying drawings, wherein like reference numerals designate like structural elements.

FIGS. 1A and 1B show an example of an electronic device.

FIG. 2 shows an example block diagram of an electronic device.

FIG. 3A illustrates an example layout of a pixel array.

FIG. 3B illustrates a plan view of a dual function light transmit and receive pixel array at a first time, according to an embodiment.

FIG. 3C illustrates a plan view of the dual function light transmit and receive pixel array of FIG. 3A at a second time, according to an embodiment.

FIG. 4 illustrates a perspective view of an example structure of a single dual function light transmit and receive pixel within a dual function light transmit and receive pixel array.

FIG. 5A illustrates a cross-section of a structure of semiconductor layers of a dual function light transmit and receive pixel array, according to an embodiment.

FIG. 5B illustrates a cross-section of another structure of semiconductor layers of a dual function light transmit and receive pixel array, according to an embodiment.

FIG. 5C illustrates a modified structure of a dual function light transmit and receive pixel to which electrical connections are attached, according to an embodiment.

FIG. 6 illustrates a cross-section of a section of a row of a dual function light transmit and receive pixel array, according to an embodiment.

FIG. 7A illustrates a cross-section of a display and a dual function light transmit and receive pixel array, according to an embodiment.

FIG. 7B illustrates a cross-section of a display and a dual function light transmit and receive pixel array, according to an embodiment.

FIG. 7C illustrates a cross-section of a display and a dual function light transmit and receive pixel array, according to an embodiment.

FIG. 7D illustrates a cross-section of a display and a dual function light transmit and receive pixel array, according to an embodiment.

FIG. 8 illustrates a wide field of view and a zoomed field of view, such as may occur in one or more cameras, according to an embodiment.

FIG. 9A illustrates a pixel array of dual function light transmit and receive pixels that may be used as part of an AR/VR system, according to an embodiment;

FIG. 9B illustrates a configuration of a pixel array of dual function light transmit and receive pixels used in conjunction with an optical system, according to an embodiment.

FIG. 9C illustrates another configuration of a pixel array of dual function light transmit and receive pixels used in conjunction with an optical system, according to an embodiment.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The embodiments described herein are directed to electronic devices having controllable or programmable optical sensors that include an array of pixels, of which at least some pixels may be structured both to emit light and receive light. Examples of such electronic devices include, but are not limited to, smart phones, laptop computers, security systems, digital cameras, and the like. In some embodiments, such optical sensors of the electronic devices may be part of imaging systems of the electronic devices. In some embodiments, such optical systems may be used in conjunction with a display of the electronic devices.

Such arrays of pixels of the electronic devices may include dual function light transmit and receive pixels, in which such pixels include both a photodiode (PD) and a vertical-cavity, surface emitting laser (VCSEL) diode. The PD and VCSEL diode of a pixel may be formed in a common set of epitaxial layers, with both the PD and VCSEL diode vertically stacked, one above the other, along the direction perpendicular to the plane of the common set of epitaxial layers. In this configuration, light emitted from the VCSEL diode is emitted (or ‘transmitted’) along the direction perpendicular to the plane of the common set of epitaxial layers to exit the array.

The common set of epitaxial layers for the PDs and VCSEL diodes, for some or all of the pixel of the array, may be initially formed in series, such as by deposition, across a substrate. Thereafter, regions may be formed, such as by etching, into the common set of epitaxial layers, through which electrical connections to the PD and VCSEL diode structures of pixels are formed, together with electrically insulating material to provide electrical separation of the pixels of the array.

Each pixel may have its functionality alterable or controllable by a controller or processor, which may be either integrated with a pixel array or located on a separate component of the electronic device. In one case, the PD structure within the pixel may be biased through the electrical connections so that the PD functions as a light detector. In another case, the VCSEL diode may be biased through the electrical connections to emit laser light, such as pulsed laser light.

The array of pixel may be attached or otherwise connected to a backplane, or to a separately formed chip, that includes electrical circuitry such as transistors, electrical vias or interconnects, processors or controllers, or other components electrically linked with the pixel of the array. These other components may provide the biases that select the function of each pixel of the array.

The pixels of an array may be individually programmed or biased to function either as a PD or as a VCSEL diode, and such functionality may be altered at different times. An array of pixels may at a first time be programmed or configured to have a majority of the pixels function as PDs, such as for optical sensing in a low light situation of an exterior environment of the electronic device. Alternatively, at a second time, the array of pixels may be reprogrammed or reconfigured to have a majority of the pixels function as VCSEL diodes, such as for depth sensing or range finding to objects exterior to the electronic device.

In one family of embodiments, electronic devices are described that have both an electronic display facing the device's exterior, and an array of pixels positioned behind the array (e.g., interior to the device). Controllers or processors of the electronic devices may select a subset of the pixels that have been determined to have their respective VCSEL diodes transmit their laser light through light transmissive openings between the light emitting components of the electronic display. The selected pixels may be used for depth sensing or range finding. Using only a subset of the pixels of the array may allow for reduced power consumption by the array.

In this family of embodiments, a controller may perform a selection process to redetermine which pixels of the array to use as light emitters. Such a selection process may be implemented, for example, periodically or when an impact to the device is detected.

In another family of embodiments, both one (or more) cameras and an array of pixels are configured adjacent to a light input/output surface of an electronic device. The pixels of the array may be dynamically correlated, or ‘registered,’ with areas of the field of view of the camera. In the case of a desired location in the camera's field of view for focusing, just the registered or corresponding pixels of the array may be used for depth sensing or range finding.

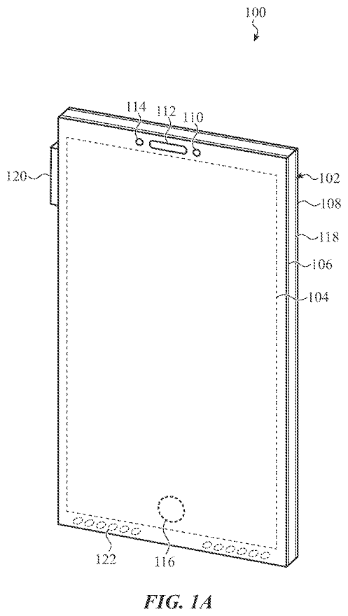

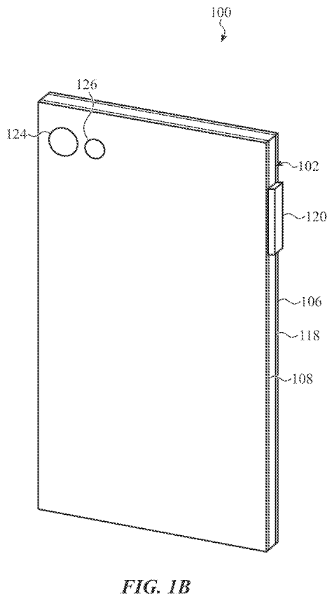

These and other embodiments are discussed below with reference to FIGS. 1A-8. However, those skilled in the art will readily appreciate that the detailed description given herein with respect to these Figures is for explanatory purposes only and should not be construed as limiting.

Directional terminology, such as “top”, “bottom”, “upper”, “lower”, “front”, “back”, “over”, “under”, “above”, “vertical”, “horizontal”, “below”, “left”, “right”, etc. is used with reference to the orientation of some of the components in some of the figures described herein. Because components in various embodiments can be positioned in a number of different orientations, directional terminology is used for purposes of illustration and is not always limiting. Directional terminology is intended to be construed broadly, and therefore should not be interpreted to preclude components being oriented in different ways. Also, as used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or one of any combination of the items, and/or one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

FIGS. 1A and 1B show an example of a device 100 that may include an illumination projector. The device's dimensions and form factor, including the ratio of the length of its long sides to the length of its short sides, suggest that the device 100 is a mobile phone (e.g., a smartphone). However, the device's dimensions and form factor are arbitrarily chosen, and the device 100 could alternatively be any portable electronic device including, for example a mobile phone, tablet computer, portable computer, portable music player, wearable device (e.g., an electronic watch, health monitoring device, or fitness tracking device), augmented reality (AR) device, virtual reality (VR) device, mixed reality (MR) device, gaming device, portable terminal, digital single-lens reflex (DSLR) camera, video camera, vehicle navigation system, robot navigation system, or other portable or mobile device. The device 100 could also be a device that is semi-permanently located (or installed) at a single location. FIG. 1A shows a front isometric view of the device 100, and FIG. 1B shows a back isometric view of the device 100. The device 100 may include a housing 102 that at least partially surrounds a display 104. The housing 102 may include or support a front cover 106 that defines a front surface of the device 100, and/or a back cover 108 that defines a back surface of the device 100 (with the back surface opposite the front surface). More generically, the device 100 may include one or more “covers.” The front cover 106 may be positioned over the display 104, and may provide a window through which the display 104 may be viewed. In some embodiments, the display 104 may be attached to (or abut) the housing 102 and/or the front cover 106. In alternative embodiments of the device 100, the display 104 may not be included and/or the housing 102 may have an alternative configuration.

The display 104 may include one or more light-emitting elements, and in some cases may be a light-emitting diode (LED) display, an organic LED (OLED) display, a liquid crystal display (LCD), an electroluminescent (EL) display, thin film transistor (TFT) display, or another type of display. In some embodiments, the display 104 may include, or be associated with, one or more touch and/or force sensors that are configured to detect a touch and/or a force applied to a surface of the front cover 106. As described below, the display 104 may be used in conjunction with an array of pixels, such as an array of dual function light transmit and receive pixels.

The various components of the housing 102 may be formed from the same or different materials. For example, a sidewall 118 of the housing 102 may be formed using one or more metals (e.g., stainless steel), polymers (e.g., plastics), ceramics, or composites (e.g., carbon fiber). In some cases, the sidewall 118 may be a multi-segment sidewall including a set of antennas. The antennas may form structural components of the sidewall 118. The antennas may be structurally coupled (to one another or to other components) and electrically isolated (from each other or from other components) by one or more non-conductive segments of the sidewall 118. The front cover 106 may be formed, for example, using one or more of glass, a crystal (e.g., sapphire), or a transparent polymer (e.g., plastic) that enables a user to view the display 104 through the front cover 106. In some cases, a portion of the front cover 106 (e.g., a perimeter portion of the front cover 106) may be coated with an opaque ink to obscure components included within the housing 102. The back cover 108 may be formed using the same material(s) that are used to form the sidewall 118 or the front cover 106. In some cases, the back cover 108 may be part of a monolithic element that also forms the sidewall 118 (or in cases where the sidewall 118 is a multi-segment sidewall, those portions of the sidewall 118 that are conductive or non-conductive). In still other embodiments, all of the exterior components of the housing 102 may be formed from a transparent material, and components within the device 100 may or may not be obscured by an opaque ink or opaque structure within the housing 102.

The front cover 106 may be mounted to the sidewall 118 to cover an opening defined by the sidewall 118 (i.e., an opening into an interior volume, in which various electronic components of the device 100, including the display 104, may be positioned). The front cover 106 may be mounted to the sidewall 118 using fasteners, adhesives, seals, gaskets, or other components.

A display stack or device stack (hereafter referred to as a “stack”) including the display 104 may be attached (or abutted) to an interior surface of the front cover 106 and extend into the interior volume of the device 100. In some cases, the stack may include a touch sensor (e.g., a grid of capacitive, resistive, strain-based, ultrasonic, or other type of touch sensing elements), or other layers of optical, mechanical, electrical, or other types of components. In some cases, the touch sensor (or part of a touch sensor system) may be configured to detect a touch applied to an outer surface of the front cover 106 (e.g., to a display surface of the device 100). In some embodiments, the stack may include an array of dual function light transmit and receive pixels.

In some cases, a force sensor (or part of a force sensor system) may be positioned within the interior volume above, below, and/or to the side of the display 104 (and in some cases within the device stack). The force sensor (or force sensor system) may be triggered in response to the touch sensor detecting one or more touches on the front cover 106 (or a location or locations of one or more touches on the front cover 106), and may determine an amount of force associated with each touch, or an amount of force associated with a collection of touches as a whole. In some embodiments, the force sensor (or force sensor system) may be used to determine a location of a touch, or a location of a touch in combination with an amount of force of the touch. In these latter embodiments, the device 100 may not include a separate touch sensor.

As shown primarily in FIG. 1A, the device 100 may include various other components. For example, the front of the device 100 may include one or more front-facing cameras 110, speakers 112, microphones, or other components 114 (e.g., audio, imaging, and/or sensing components) that are configured to transmit or receive signals to/from the device 100. In some cases, a front-facing camera 110, alone or in combination with other sensors, may be configured to operate as a bio-authentication or facial recognition sensor. The device 100 may also include various input devices, including a mechanical or virtual button 116, which may be accessible from the front surface (or display surface) of the device 100. In some embodiments, a virtual button 116 may be displayed on the display 104 and, in some cases, a fingerprint sensor may be positioned under the button 116 and configured to image a fingerprint through the display 104. In some embodiments, the fingerprint sensor or another form of imaging device may span a greater portion, or all, of the display area.

The device 100 may also include buttons or other input devices positioned along the sidewall 118 and/or on a back surface of the device 100. For example, a volume button or multipurpose button 120 may be positioned along the sidewall 118, and in some cases may extend through an aperture in the sidewall 118. In other embodiments, the button 120 may take the form of a designated and possibly raised portion of the sidewall 118, but the button 120 may not extend through an aperture in the sidewall 118. The sidewall 118 may include one or more ports 122 that allow air, but not liquids, to flow into and out of the device 100. In some embodiments, one or more sensors may be positioned in or near the port(s) 122. For example, an ambient pressure sensor, ambient temperature sensor, internal/external differential pressure sensor, gas sensor, particulate matter concentration sensor, or air quality sensor may be positioned in or near a port 122.

In some embodiments, the back surface of the device 100 may include a rear-facing camera 124 that includes one or more image sensors (see FIG. 1B). In some cases, the device 100 may have a second imaging sensor 126, which may be an autofocus camera, a telephoto camera, a second camera used in conjunction with the rear-facing camera 124—such as to provide depth or 3D imaging—or another optical sensor. The device 100 may also have a flash or light source that may be positioned on the back of the device 100 (e.g., near the rear-facing camera). In some cases, the back surface of the device 100 may include multiple rear-facing cameras.

One or both of the rear-facing camera 124 and the second imaging sensor 126 may include one or more pixel arrays. The pixels of such pixel arrays may be dual function light transmit and receive pixels, as described herein.

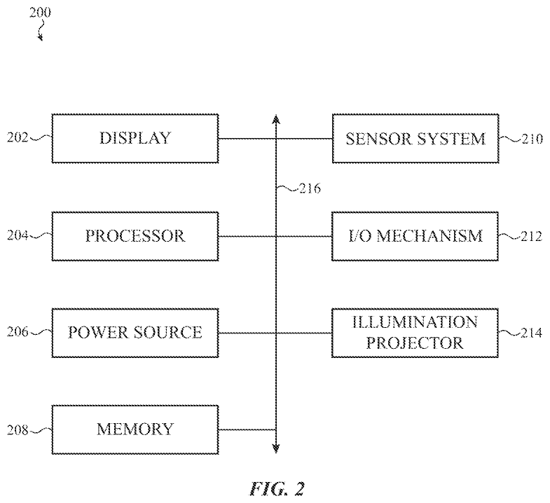

FIG. 2 shows an example block diagram of an electronic device 200, which in some cases may be the electronic device described with reference to FIGS. 1A and 1B, or another type of electronic device including one or more of the image sensors having one or more pixel arrays as described herein. The electronic device 200 may include an electronic display 202 (e.g., a light-emitting display), a processor 204, a power source 206, a memory 208 or storage device, a sensor system 210, an input/output (I/O) mechanism 212 (e.g., an input/output device, input/output port, or haptic input/output interface), and/or an illumination projector 214. The processor 204 may control some or all of the operations of the electronic device 200. The processor 204 may communicate, either directly or indirectly, with some or all of the other components of the electronic device 200. For example, a system bus, other bus(es), or other communication mechanism 216 can provide communication between the electronic display 202, the processor 204, the power source 206, the memory 208, the sensor system 210, the I/O mechanism 212, and the illumination projector 214.

The processor 204 may be implemented as any electronic device capable of processing, receiving, or transmitting data or instructions, whether such data or instructions is in the form of software or firmware or otherwise encoded. For example, the processor 204 may include a microprocessor, a central processing unit (CPU), an application-specific integrated circuit (ASIC), a digital signal processor (DSP), a controller, or a combination of such devices. As described herein, the term “processor” is meant to encompass a single processor or processing unit, multiple processors, multiple processing units, or other suitably configured computing element or elements. In some cases, the processor 204 may provide part or all of the processing system or processor described herein.

It should be noted that the components of the electronic device 200 can be controlled by multiple processors. For example, select components of the electronic device 200 (e.g., the sensor system 210) may be controlled by a first processor and other components of the electronic device 200 (e.g., the electronic display 202) may be controlled by a second processor, where the first and second processors may or may not be in communication with each other.

The power source 206 can be implemented with any device capable of providing energy to the electronic device 200. For example, the power source 206 may include one or more batteries or rechargeable batteries. Additionally or alternatively, the power source 206 may include a power connector or power cord that connects the electronic device 200 to another power source, such as a wall outlet.

The memory 208 may store electronic data that can be used by the electronic device 200. For example, the memory 208 may store electrical data or content such as, for example, audio and video files, documents and applications, device settings and user preferences, timing signals, control signals, instructions, and/or data structures or databases. The memory 208 may include any type of memory. By way of example only, the memory 208 may include random access memory, read-only memory, Flash memory, removable memory, other types of storage elements, or combinations of such memory types.

The electronic device 200 may also include one or more sensor systems 210 positioned almost anywhere on the electronic device 200. The sensor system(s) 210 may be configured to sense one or more types of parameters, such as but not limited to, vibration; light; touch; force; heat; movement; relative motion; biometric data (e.g., biological parameters) of a user; air quality; proximity; position; connectedness; surface quality; and so on. By way of example, the sensor system(s) 210 may include a heat sensor, a position sensor, a light or optical sensor, a self-mixing interferometry (SMI) sensor, an image sensor (e.g., one or more of the image sensors or cameras described herein), an accelerometer, a pressure transducer, a gyroscope, a magnetometer, a health monitoring sensor, an air quality sensor, and so on. Additionally, the one or more sensor systems 210 may utilize any suitable sensing technology, including, but not limited to, interferometric, magnetic, capacitive, ultrasonic, resistive, optical, acoustic, piezoelectric, or thermal technologies.

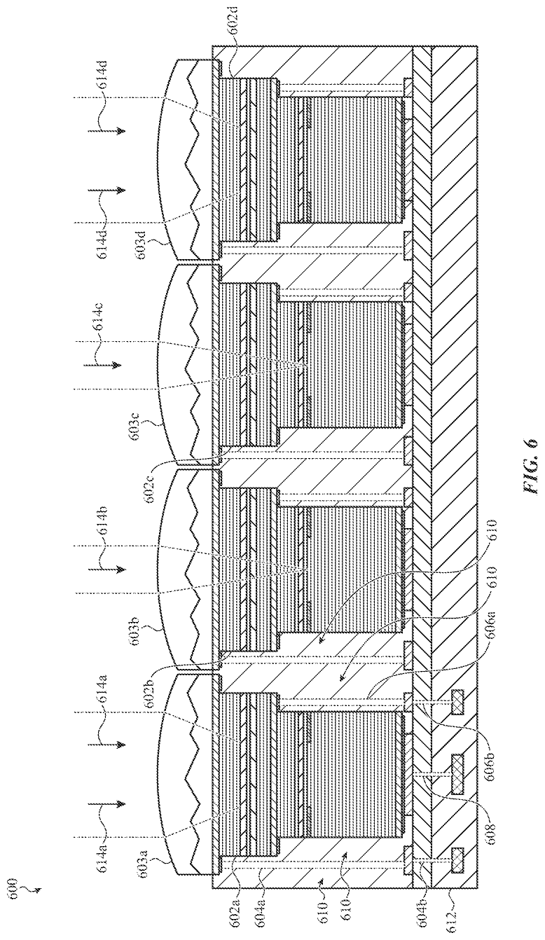

In particular, the sensor system(s) 210 of the electronic device 200 may include one or more cameras, or other types of image sensors or active optical sensors, that include pixel arrays as described herein, and which may be operated or controlled, such as by the processor 204, by the methods described herein in relation to FIGS. 6, 7, and 8.

The I/O mechanism 212 may transmit or receive data from a user or another electronic device. The I/O mechanism 212 may include the electronic display 202, a touch sensing input surface, a crown, one or more buttons (e.g., a graphical user interface “home” button), one or more microphones or speakers, one or more ports such as a microphone port, and/or a keyboard. Additionally or alternatively, the I/O mechanism 212 may transmit electronic signals via a communications interface, such as a wireless, wired, and/or optical communications interface. Examples of wireless and wired communications interfaces include, but are not limited to, cellular and Wi-Fi communications interfaces.

The illumination projector 214 may be configured as described with reference to FIGS. 1A and 1B and elsewhere herein, and in some cases may be integrated or used in conjunction with one or more of the sensor system(s) 210. For example, the illumination projector 214 may illuminate an object or scene, and light that reflects or scatters from the object or scene may be sensed by a light or optical sensor, an SMI sensor, or an image sensor (e.g., one or more of the image sensors or cameras described herein). In some embodiments, an illumination projector 214 may be part of a sensor system 210.

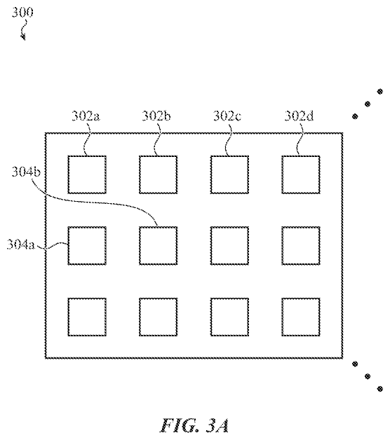

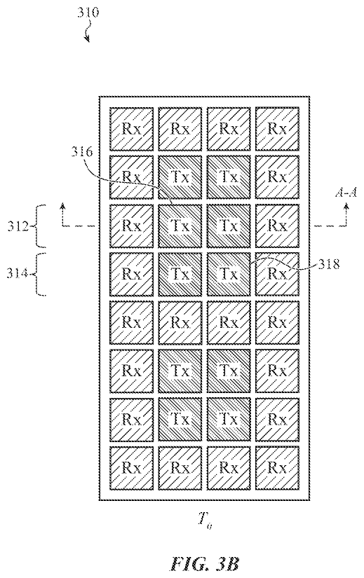

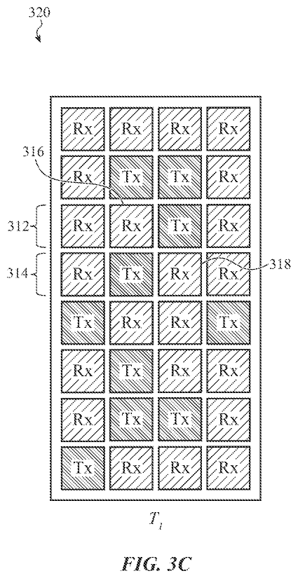

FIG. 3A shows a plan view (e.g., a top view) of a section of a pixel array 300 that may be a component of an optical sensor, such as the camera 124 or the imaging sensor 126. The pixel array 300 may be configured as a rectangular array, with a first row containing the individual pixels 302a-d. A second row of the pixel array 300 includes the pixel 304a in the same column as pixel 302a of the first row, and pixel 304b in the same column as pixel 302b of the first row. The rows and columns of the pixel array 300 may extend to form an M×N array of M rows and N columns, for M and N large integers. In some embodiments, M and N may be on the order of 10³ or more. One skilled will recognize that, in other embodiments, alternate geometric configurations for the pixels of pixel array 300 are possible, such as a hexagonal array of pixels arranged in an area-filling configuration with shifted rows.

The various pixels of the pixel array 300 may be able to switch functionality, or “configuration,” either to receive incoming light, or to emit, or “transmit” light. Certain embodiments of pixels with such reconfigurable functionality are described below, in which the pixels are formed with both a photodiode (PD) and a vertical-cavity, surface-emitting laser (VCSEL) diode in a common set of semiconductor epitaxial layers. The semiconductor epitaxial layers may be formed initially on a single substrate, with subsequent electrical isolation of the reconfigurable pixels by etching of the semiconductor epitaxial layers, deposition of insulating material, and other operations. Pixels with such reconfigurable functionality are herein termed dual function light transmit and receive pixels, or ‘dual function pixels’ or just ‘pixels’ when clear from contest. The functional reconfiguration of such pixels may be accomplished by applying different electrical biases to electrical contacts of the pixels, with such electrical biases implemented by a controller and/or processor. The electrical biases may include voltages from voltage sources on or exterior to the pixel array. The voltages may be applied to the electrical contacts through switching or control circuitry controlled by the controller or processor.

FIGS. 3B and 3C illustrate two operational configurations 310 and 320 of a section of the pixel array 300, in which the pixels are dual function pixels, at two different times T₀ and T₁. At time T₀, in the configuration 310, various pixels of the pixel array, indicated by Tx, have been configured to transmit light, while others have been configured to receive light, indicated by Rx. The configurations may be implemented by applying corresponding electrical biases to the pixels, such as by a controller or processor electrically linked with the pixels. In particular, in the third row 312, the pixel 316 has been configured to emit or transmit light, as has the pixel 318 of the fourth row 314. A cross-section view along the cut lines A-A is shown in FIG. 6.

At another time T₁, as shown in FIG. 3C, various pixels of the pixel array have been reconfigured: the pixels 316 and 318 in particular have been reconfigured to receive light.

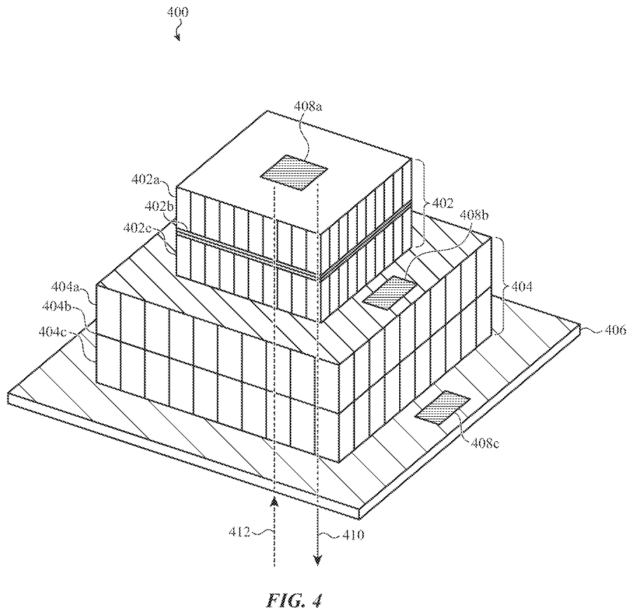

FIG. 4 shows a perspective view of a single dual function pixel 400 from an array of dual function pixels. The pixel 400 includes a VCSEL diode formed in a first set of epitaxial semiconductor layers (or “epitaxial layers”, or just “layers”) 402, and a PD formed in a second set of layers 404. Another layer may be a contact layer 406, and may be the layer of the pixel array that faces exterior incoming light 412.

The pixel 400 includes three electrical contacts 408a, 408b, and 408c. A first electrical bias may be applied at least at the electrical contacts 408a and 408b to configure the VCSEL diode formed in the first set of layers 402 to emit light. A second electrical bias may be applied at least at the electrical contacts 408b and 408c to configure the PD in the second set of layers 404 to receive light. For convenience of illustration, the electrical contacts 408a-c are shown as localized rectangles, but one skilled in the art will understand that the electrical contacts 408a-c may extend further around and/or between the respective layers on which they are illustrated.

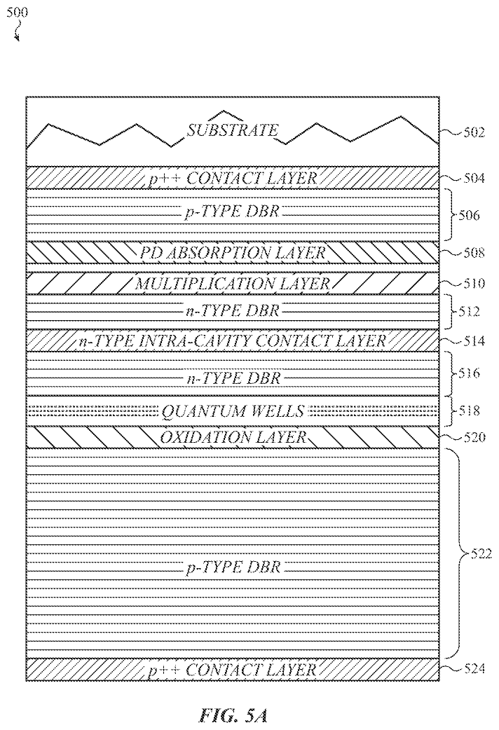

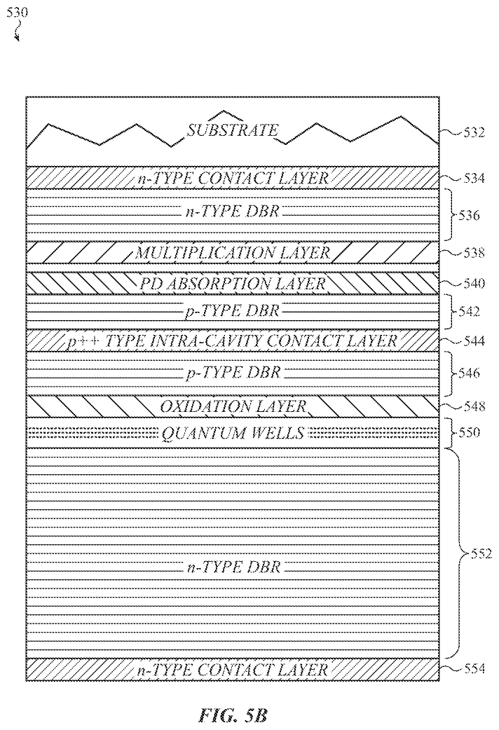

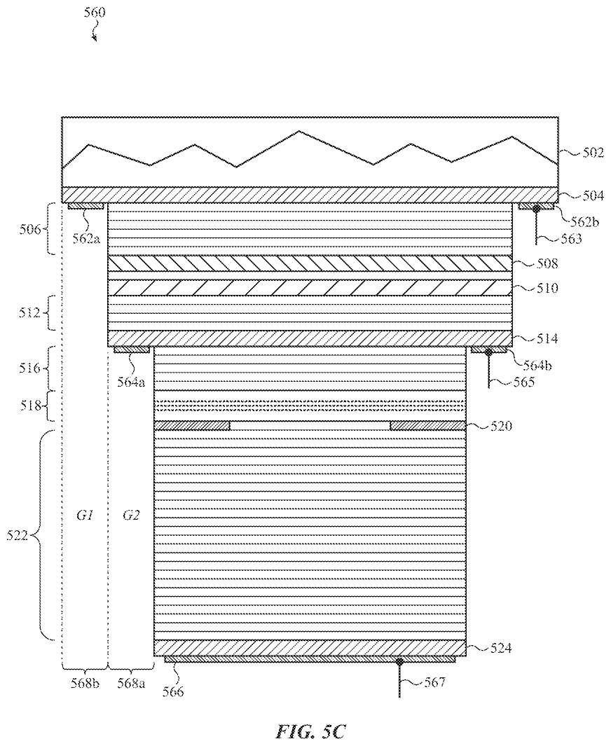

The VCSEL diode formed in the first set of layers 402 may include one or more quantum wells in the quantum well layer 402b. The VCSEL diode in the layers 402 may include a first distributed Bragg reflector (DBR) 402a formed in multiple layers of a first doping type, and a second DBR 402c of a second doping type. Further details of the structure of the VCSEL diode in the second set of epitaxial layers 404 will be described in relation to FIGS. 5A-C. When the first electrical bias is a forward bias and is applied at the electrical contacts 408a and 408b, the VCSEL diode may emit light 410 that passes through the second set of layers 404 and the contact layer 406 and exits the array.

The PD in the second set of epitaxial layers 404 may have a p-n junction 404b formed at an interface between a first set of layers 404a of a first doping type and a second set of layers 404c of a second doping type. Further details of the structure of the PD in the second set of epitaxial layers 404 will be described in relation to FIGS. 5A-C. Exterior incoming light 412 impinging on the pixel 400 may be received in the PD; when the PD has the second electrical bias applied, a signal, such as a voltage or photocurrent signal, may be detected between the electrical contacts 408b and 408c.

FIG. 5A shows a cross-sectional view of a configuration 500 of a common set of epitaxial layers, from which multiple dual function pixels of a pixel array may be formed. The epitaxial layers may be grown or formed, such as by deposition, sequentially on a substrate 502. Examples of materials for the substrate 502 include, but are not limited to, GaAs, InP, and GaSb, and may be chosen to match the lattice structure of the various deposited semiconductor epitaxial layers. In the embodiment with the configuration 500, a first p++ type contact layer 504 is formed on the substrate 502. The first p++ type contact layer 504 may have or connect to an electrical contact of an electrical bias source, such as a voltage source.

Next to the p++ type contact layer 504, are epitaxial layers from which a PD of a pixel is formed. These epitaxial layers include layers forming a first p-type distributed Bragg reflector (DBR) 506, a PD absorption layer 508, an optional multiplication layer 510, and layers for a first n-type DBR 512. Photodiodes so formed may be specific embodiments of the PD of the pixel 400 in the layers 404 of FIG. 4.

The PD absorption layer 508 may be formed as one of: a single bulk layer, or multiple quantum wells of epitaxial material, such as InGaAs, InGaAsN, InGaAsP, or another material. If there is no multiplication layer 510, the PD formed by the first p-type DBR 506, the PD absorption layer 508, and the first n-type DBR 512 has the functionality of the resonant cavity photodiode. If there is an included multiplication layer 510, the PD formed by the first p-type DBR 506, the PD absorption layer 508, the multiplication layer 510, and the first n-type DBR 512 instead has the functionality of either a resonant cavity, avalanche photodiode (RC-APD), or a resonant cavity, single-photon avalanche diode (RC-SPAD).

An n-type intra-cavity contact layer 514 is positioned between the first n-type DBR 512 and a second n-type DBR 516. The n-type intra-cavity contact layer 514 may include or connect to an electrical bias source, such as a voltage source.

Opposite to the n-type intra-cavity contact layer 514 from the layers for a first n-type DBR 512 are the layers from which a VCSEL diode of a pixel is formed. These layers include the 4 layers forming a second n-type DBR 516, quantum well layers 518, an oxidation layer 520, and layers forming a second p-type DBR 522.

Beneath the second p-type DBR 522 is a second p++ type contact layer 524. The second p++ type contact layer 524 may have or connect to another electrical contact of an electrical bias source, such as a voltage source.

The epitaxial layers of the first and second p-type DBR 506 and 522, and the first and second n-type DBR 512 and 516, may include multiple pairs of layers, of alternating materials having different refractive indices, of the respective doping type, each pair of layers forming a Bragg pair. An exemplary pair of materials that may be used to form a distributed Bragg reflector 303b are aluminum arsenide and GaAs. The material for the first and second p-type DBR 506 and 522, and the first and second n-type DBR 512 and 516, may be one of: a purely epitaxial material such as AlGaAs, AlGaInP, or another such epitaxial material; a purely dielectric material; or a hybrid material.

The material of the quantum well layer 518 may similarly be one of: a purely epitaxial material such as AlGaAs, AlGaInP, or another such epitaxial material; a purely dielectric material; or a hybrid material. In the quantum well layer 518 there may be either one group of quantum wells, or multiple groups of quantum wells, so that the resulting VCSEL diode is, respectively, a single junction or a multi-junction VCSEL diode.

FIG. 5B shows a cross-section of an alternative configuration 530 of a common set of epitaxial layers, from which multiple pixels of a pixel array may be formed. The epitaxial layers of the alternative configuration 530 are analogous to the common set of epitaxial layers of the configuration 500, but the doping types of various layers are reversed.

More specifically, on a substrate 532, a first n-type contact layer 534 is formed. On the first n-type contact layer 534 are epitaxial layers from which a PD of a pixel is formed: layers of a first n-type DBR 536, an optional multiplication layer 538, a PD absorption layer 540, and layers of a first p-type DBR 542.

Beneath the layers of the first p-type DBR 542 is a p++ type intracavity contact layer 544, at which an electrical contact may be positioned to connect to an electrical bias source.

Beneath the first p-type DBR 542 are layers from which a VCSEL diode of a pixel may be formed: a second p-type DBR 546, an oxidation layer 548, a quantum wells layer 550, and layers of a second n-type DBR 552.

Beneath the second n-type DBR 552 is a second n-type contact layer 554 at which an electrical contact may be positioned to connect to an electrical bias source.

The functionality and materials of the first and second n-type DBRs 536 and 552, and the first and second p-type DBRs 542 and 546 are as described for the first and second n-type DBRs 512 and 516, and the first and second p-type DBRs 506 and 522 of the configuration 500.

The functionality of the PD and VCSEL diode that are formed in the epitaxial layers of the configuration 530 are as described for the PD and VCSEL diode that are formed in the epitaxial layers of the configuration 500, except for changes, recognizable by one skilled in the art, due to the reversed doping types.

FIG. 5C shows a cross-section view of a configuration 560 of the epitaxial layers of configuration 500 of FIG. 5A after further processing and addition of at least electrical connections and insulating material. The components and epitaxial layers with like reference numbers to those of FIG. 5A are as described in relation to FIG. 5A.

In the configuration 560, a first vertical ‘trench’ or gap G1 568a is formed, such as by etching, from the second p++ contact layer 524 to the first p++ type contact layer 504. The trench G1 568a extends around the epitaxial layers to form a first mesa structure that includes the first p-type DBR 506, the PD absorption layer 508, the optional multiplication layer 510, the first n-type DBR 512, and the n-type intra-cavity contact layer 514. The shape of the first mesa structure may, for example, have a rectangular box shape as shown in FIG. 4, or may be cylindrical with a circular or ellipsoidal cross-section, or have another shape. Electrical contacts 562a and 562b have been added to the surface of the first p++ contact layer opposite to the substrate 502. The two electrical contacts 562a and 562b may be connected; for example, by extending at least partially around the first mesa structure on the bottom surface of the first p++ contact layer. An electrical connection 563 may extend from the electrical contact 562b to other components exterior to the pixels, such as to one or more voltage sources with voltages regulated or applied by a controller.

A second vertical gap or ‘trench’ G2 568b has been etched from the second p++ contact layer 524 up to the n-type intra-cavity contact layer 514. The second trench 568b also extends around the epitaxial layers to form a second, narrower mesa structure that includes the second n-type DBR 516, the quantum well layer(s) 518, the oxidation layer 520 and the second p-type DBR layers 522.

Electrical contacts 564a and 564b have been added to the n-type intra-cavity contact layer 514. The electrical contacts 564a and 564b may form a single connected contact by extending at least partially around the bottom surface of the n-type intra-cavity contact layer 514. An electrical connection 565 may extend from the electrical contact 564b to other components exterior to the pixels, such as to one or more voltage sources with voltages regulated or applied by a controller. An electrical bias may be applied to the PD structure with a first voltage applied at the electrical contacts 562a and/or 562b, and a second voltage applied at the electrical contacts 564a and/or 564b.

An electrical contact 566 has been added to the second p++ contact layer 524 on the side opposite to the second p-type DBR 522. An electrical connection 567 may extend from the electrical contact 566 to other components exterior to the pixels, such as to one or more voltage sources with voltages regulated or applied by a controller. An electrical bias may be applied to the VCSEL diode structure with a first voltage applied at the electrical contacts 564a and/or 564b, and a second voltage applied at the electrical contact 566.

An insulating or dielectric material, such as SiO₂ may be formed, such as by deposition, in the trench G1 568a and the trench G2 568b after the electrical contacts 562a, 562b, 564a, 564b, and 566 have been added to provide electrical isolation between pixels. A further extension of the insulating material (not shown) may extend through the first p++ contact layer to the substrate 502 to provide electrical separation of the pixels.

When the pixel with the configuration 560 is to operate as a PD, it may be reversed biased by applying a negative voltage to the electrical contacts 562a and 562b, with a ground voltage at electrical contacts 564a and 564b. Also, a ground voltage may be applied to electrical contact 566 so that the VCSEL diode section of the pixel is unbiased. When the pixel is to operate as a light emitter, the electrical contacts 564a and 564b may have a ground voltage applied, while the electrical contact 566 has a positive voltage applied so that the VCSEL diode section is forward biased. Also, the electrical contacts 562a and 562b may also have a ground voltage applied so that the PD section is unbiased.

One skilled in the art will recognize that analogous formation of trenches and mesa structures, and addition of electrical contacts, connections, and insulating material may be applied to the configuration 530 of epitaxial layers shown in FIG. 5B.

FIG. 6 shows a cross-sectional view along a section of a row of dual function pixels of a pixel array 600. The cross-sectional view may, for example, be along the cut lines A-A of the pixel array 300 shown in FIG. 3B. Shown are four pixels: 602a, 602b, 602c, and 602d, which may be formed from a common set of epitaxial layers as described in relation to FIGS. 5A-C. Insulating material 610 is shown separating the pixels 602a and 602b. The insulating material 610 also forms separations between the other pixels, but for clarity is not referenced.

For the pixel array 600, the substrate layer, such as substrate 502 of FIG. 5A, on which the common set of epitaxial layers may have been formed, may have been removed, at least in part, and light focusing lenses 603a, 603b, 603c, and 603d may be joined above the respective pixels 602a-d. The pixel array may be joined to a support layer 611, which may be an insulating material. In turn, the support layer 611 may be joined to a backplane 612. Alternatively, the backplane 612, may be another semiconductor chip. The backplane 612 may contain electrical connections or signal lines that connect to other electrical components, such as one or more controller or processor units, that control the biases and functionality of the pixels 602a-d.

The pixel 602a has a first electrical connection 604a that extends through the insulating material 610 and by the via 604b to a signal line in the backplane 612. The first electrical connection 604a may be configured as described for the electrical connection 563 of FIG. 5C. Similarly, the pixel 602a has a second electrical connection 608 similarly extending to a signal line in the backplane 612. The second electrical connection 608 may be configured as described for the electrical connection 567 of FIG. 5C. The pixel 602a has a third electrical connection 606a similarly extending through the insulating material 610 and the via 606b to a signal line in the backplane 612. The third electrical connection may be configured as described for the electrical connection 565 of FIG. 5C.

In the configuration of the pixel array 600 shown, the pixels 602a and 602d are configured as PD light detectors, such as by the reverse bias voltages applied to their PD sections, as described in relation to FIG. 5C, and are operable to detect respective incoming light 614a and 614d. Photons of the incoming light 614a and 614d may induce photocurrent which may be detected through the electrical connections 563 and 565.

In the configuration of the pixel array 600 shown, the pixels 602b and 602c are configured as VCSEL diodes to emit laser light, such as by having forward bias voltages applied to their VCSEL diode sections as described in relation to FIG. 5C.

In some embodiments, an electronic device having a such a programmable pixel array of pixels, such as the pixel array 600, as an optical sensor may adjust the respective number of pixels operating as PDs and as VCSEL diodes. Such an adjustment may be based on a signal-to-noise ratio, such as may be determined in a light sensing operation. As an example, in a low light environment situation, with a first number of pixels operating as PDs, the amount of light induced photocurrent detected from the PDs may not sufficiently exceed a noise current level of PDs. In such a case, a controller may reconfigure more pixels as PDs to obtain better imaging of the scene. Alternatively, in a high light exterior environment, more pixels may need to be reconfigured to function as VCSEL diodes. A controller may reconfigure the pixels of the pixel array in response to a received adjustment signal. The adjustment signal may be a based on one or more criteria or tests applied by the controller itself, or by an external input, such as from a user or a separate processor of the electronic device that contains the pixel array. As examples, a user may determine that a greater exposure is needed, and so want to increase the number of pixels configured as light receivers. Or an impact detected by the electronic device may indicate a need for a recalibration procedure or another operation. Or the recalibration or other operation may be performed after a scheduled period of time has elapsed.

In another example, the pixel array 600 may be used for ranging or depth sensing, in which the pixels configured as VCSEL diodes emit pulsed laser light, whose reflections are detected by the pixel configured as PDs. If the measured photocurrent is too low, a controller may reconfigure more pixels to function as PDs.

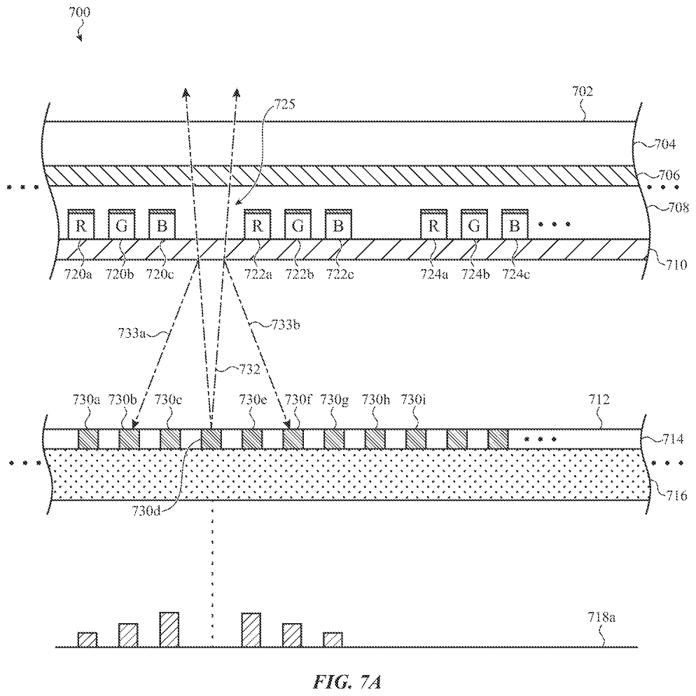

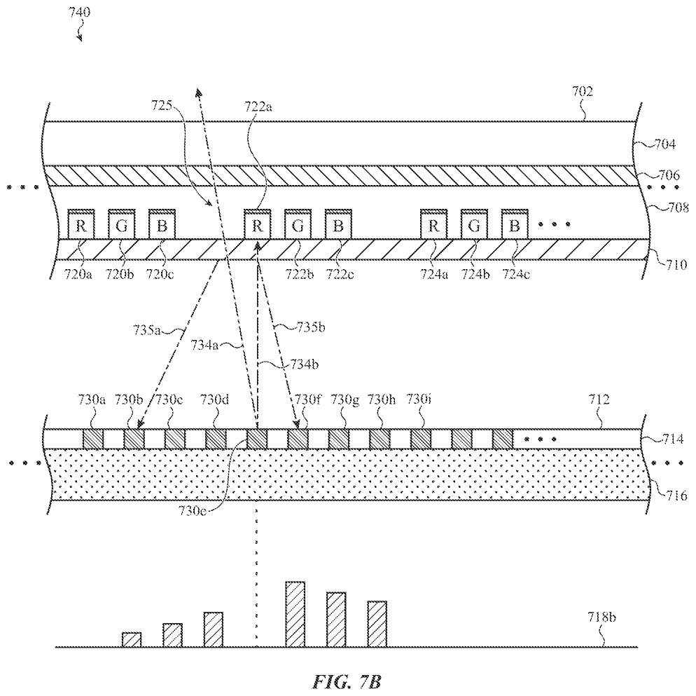

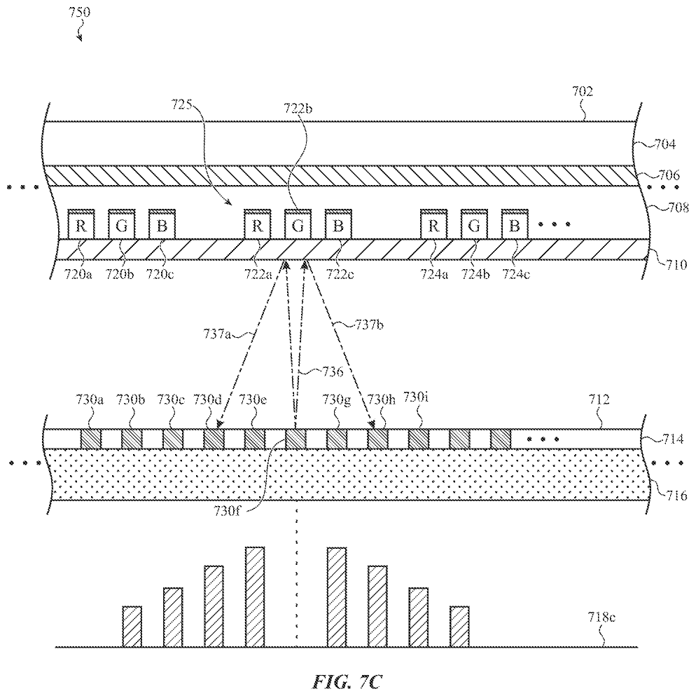

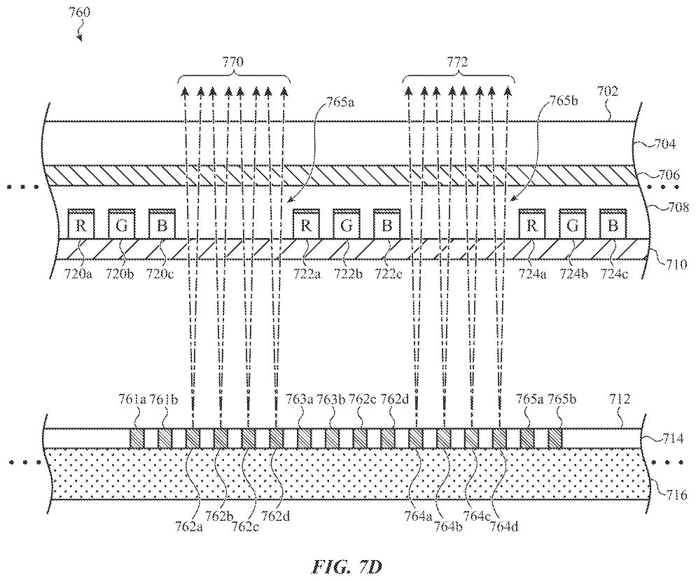

FIGS. 7A, 7B, 7C, and 7D show respective cross-sectional views 700, 740, 750, and 760 of a section of an interior of an electronic device in which there is a display screen or device 702 facing an exterior environment, behind which is a pixel array 712 of pixels. The pixels may be configured as described in relation FIGS. 5A-C and FIG. 6. An electronic device may have the pixel array 712 positioned behind the display device 702 to provide optical and/or depth sensing, such as for facial recognition capabilities on a smartphone display. The four cross-sectional views 700, 740, 750, and 760 show different operational states of the electronic device, such as may occur in a selection process by which a controller of the electronic device determines which pixels to configure for light detection (PDs reverse biased), and which pixels to configure for light emission (VCSEL diodes forward biased).

The display device 702 includes a cover glass 704, a separating layer 706, a color light emitting diode (LED) layer 708 and a backplane layer 710. The color LED layer 708 may include color emitting LEDs 720a-c, 722a-c, and 724a-c, which may each be red (R), green (G), blue (B) triplets. The color emitting LEDs 720a-c, 722a-c, and 724a-c may be organic LEDs, and the color LED layer may include thin film transistors, and possibly other components, for operational control of the LEDs.

The pixel array 712 includes a pixel layer 714 and a backplane 716. The pixel layer 714 and the backplane 716 may be configured as described for the pixel array 600 of FIG. 6. The pixel layer 714 includes at least the pixels 730a-h.

In the situation shown in FIG. 7A, the pixel 730d has been configured to transmit light 732 from its VCSEL diode section. A selected set of pixels neighboring the transmitting pixel 730d have been configured to receive light. In the cross-sectional view 700, the set of neighboring pixels includes at least the pixels 730a-c and 730e-g. In some embodiments, the selected set of neighboring pixels may be a square or rectangular region having the light transmitting pixel at its center. For example, a 7×7 or 9×9 subarray of pixels may have the light transmitting pixel at its center, with the remaining pixels configured to receive light. In other embodiments, the selected set of neighboring pixels may form a diamond shape around the central light transmitting pixel. In other embodiments, the selected set of neighboring pixels may have an alternate geometric shape, such as a hexagon or an approximately circular or elliptical shape. For simplicity of description with respect to FIGS. 7A-D, it will be assumed that the selected set of neighboring pixels extend to three pixels on each side of the light transmitting pixel.

The pixel 730d is positioned on the pixel array 712 so that its transmitted light 732 is predominantly directed toward a light transmissive gap 725 between the triple of LEDs 720a-c and the triple of LEDs 722a-c of the display device 702, and so a significant portion of the transmitted light 732 passes through the cover glass 704. Some of the transmitted light 732 may, however, be reflected from the backplane layer 710 and detected by the PDs of the selected set of neighboring pixels 730a-c and 730e-g. This is shown in the cross-sectional view 700 as the reflected light 733a and 733b received at pixels 730b and 730f. For clarity, other reflections received at other pixels of the selected set of neighboring pixels 730a-c and 730e-g are not shown.

The bar graph 718a plots respective measured values of the reflected light detected by the PDs in the selected set of neighboring pixels 730a-c and 730e-g. The measured values may be photocurrents in the PDs, voltages or voltage spikes (e.g., in the case of avalanche PDs), heat values induced in the PDs by the received reflected light 733a and 733b, or other measured values correlated with the amount of received reflected light 733a and 733b.

In the cross-sectional view 740 of FIG. 7B, the pixel 730e has been configured to transmit light 734a and 734b. However, since the pixel 730e is positioned below the end or edge of the triple of LEDs 722a-c, the light 734a mostly passes through the light transmissive gap 725 between the triples of LEDs 720a-c and 722a-c causing only a minor amount of reflected light 735a. However, the light 734b impinges on the underside of the LED 722a causing a greater amount of reflected light 735b.

As a result, the PDs of the pixels to the left of the transmitting pixel 730e in the selected set, pixels 730b-d, detect a smaller amount of the reflected light 735a compared to the amount of reflected light 735b detected by the pixels to the right of the transmitting pixel 730e in the selected set, pixels 730f-h. The resulting asymmetry in amounts of detected reflected light is plotted in the bar graph 718b. A controller of the electronic device may determine that the pixel 730e is not optimal for use as a light transmitter in other operations, such as range finding, of the electronic device.

In the cross-sectional view 750 of FIG. 7C, the pixel 730f has been configured to transmit light 736. However, since the pixel 730f is positioned below the center of the triple of LEDs 722a-c, little of the light 736 passes through the light transmissive gap 725 and then through the cover glass of the display, with most of the light 736 becoming the reflected light 737a and 737b. As a result, the PDs of the pixels both to the left and to the right of the transmitting pixel 730f in the selected set, pixels 730c-e and 730g-i, detect a larger amount of the reflected light 737a and 737b compared to the amount of reflected light 733a and 733b of FIG. 7A detected by the pixels 730a-c and 730e-g. The resulting measured values in amounts of detected reflected light is plotted in the bar graph 718c. A controller may determine that the pixel 730f should not be used as a light transmitter in other operations, such as range finding, of the electronic device.

In the cross-sectional view 760 of FIG. 7D, as a result of the testing and selection process described in relation to FIGS. 7A-C, a controller or processor of the electronic device may have selected a set of the pixels of the pixel array 712 that are optimal for use for light transmission. The controller may base its selection of a pixel to use as a light transmitter on at least one criterion related to the measured values of the detected reflected light. Further, the criterion so used may be adapted and changed, and the testing and selection process may be repeated and an updated selected set of the pixels of the pixel array 712 used as light emitters.

In the situation shown, the pixels 762a-d and 764a-d have been selected for light transmission based on a determination that an acceptable portion of their transmitted light 770 and 772 pass through the display device 702 into the exterior environment of the electronic device. The remaining pixels 761a-b, 763a-d, and 765a-b, may be either unused, or used for light detection. The controller may determine, such as by detection of ambient light conditions in the environment, that fewer of the pixels 762a-d and 764a-d are needed for light transmission operations of the electronic device.

The testing and selection process described in relation to FIGS. 7A-C may be repeated by the electronic device for at least some of the pixels of the pixel array 712, and an updated selection of the pixels of the pixel array 712 chosen for light transmission. This may occur for a variety of reasons. The testing and selection process may be repeated after an elapsed period of time, or by a user input signal. The testing and selection process may be repeated if an impact to the electronic device has been detected.

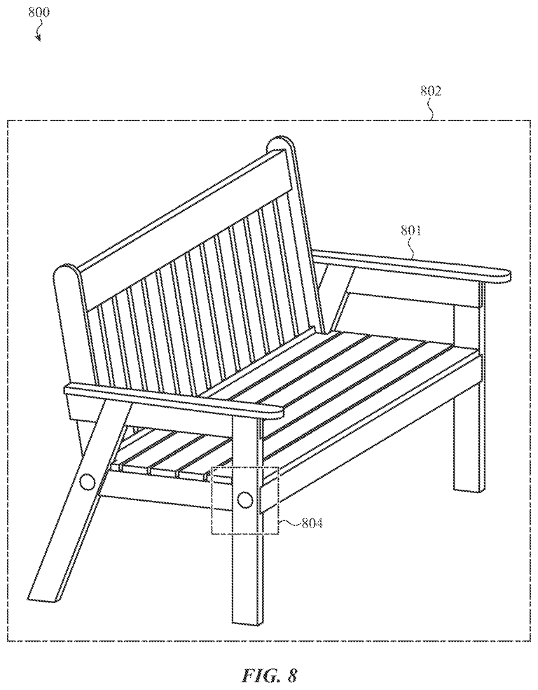

FIG. 8 shows a field of view 800 as may be received in a camera of an electronic device, such as of the camera 124 of the device 100. The electronic device may include a pixel array of pixels, either as a component of the camera, as part of a separate programmable optical sensor, or as part of an additional camera, such as a telephoto camera. The camera is operable to obtain a field of view 802 that encompasses the object 801.

The camera may be an RGB (red, green, blue) camera, and the pixel array of pixels may be used to provide depth or range finding information about the object 801. The depth information may be used for autofocusing capabilities of the camera. The field of view 800 may include a region of interest (ROI) 804. The ROI 804 may be user-defined.

In some embodiments, the pixel array of pixels may be used in conjunction with the camera, such as for focusing of the camera on the ROI. In these embodiments, the pixel array of pixels may be correlated or registered with the pixel array of the camera. With such a registration of the pixel array of pixels to the camera's pixel array, once the ROI 804 has been selected within the camera's field of view 802, a controller may configure, as VCSEL diodes and to transmit light, just the pixels of the pixel array that are registered to the camera's pixels that contain the ROI 804. This may reduce power usage in the electronic device.

In some embodiments, the pixel array of pixels may be registered or correlated with a second camera of the electronic device, either in addition to, or in lieu of, registration to the first RGB camera.

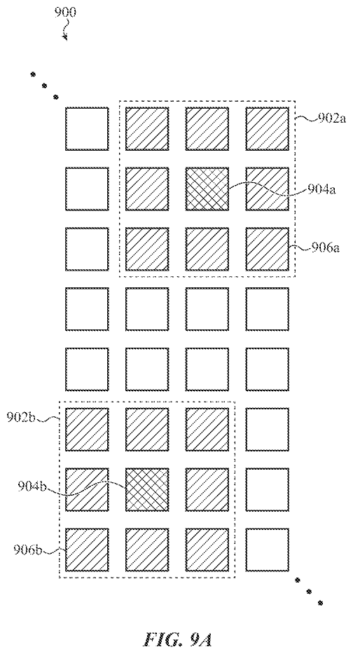

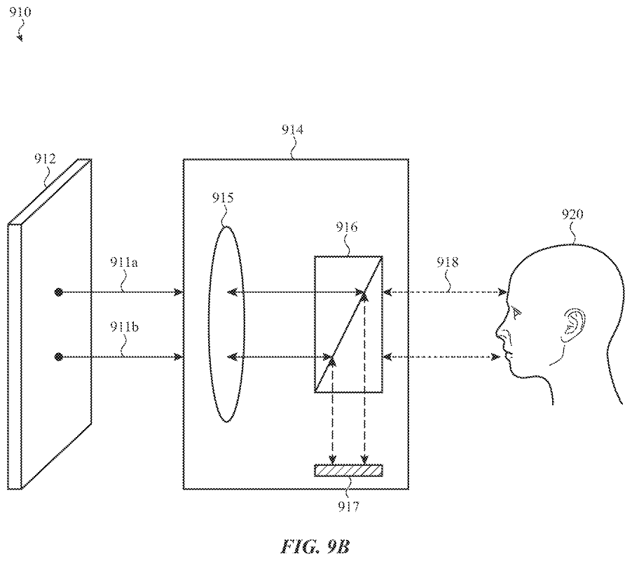

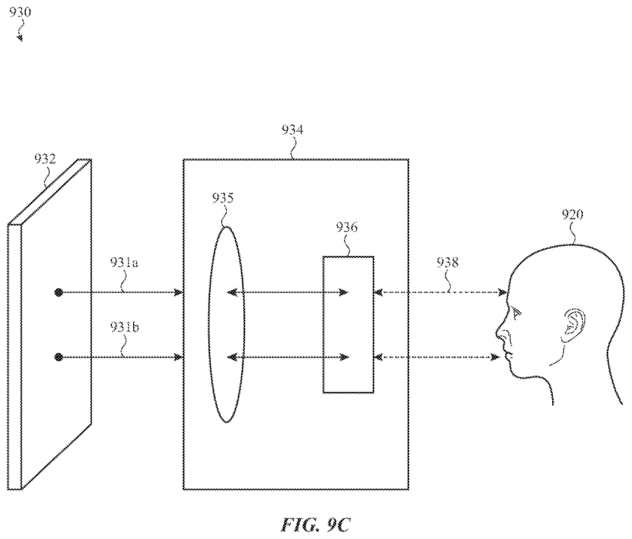

FIGS. 9A-C illustrate further applications of pixel arrays of dual function light transmit and receive pixels for use in systems or devices for augmented reality (AR), virtual reality (VR), mixed reality (MR), or extended reality (ER) which contain any combination of AR, VR, or MR functionalities. For simplicity of description, the term ER system will be used to refer to any of a AR, VR, MR, or combined AR/VR/MR device, system, or subsystem thereof. As ER devices often benefit from being compact; a single pixel array able to transmit and receive may assist in size reduction of an ER system. Such pixel arrays of dual function pixels may be used in conjunction with, or as part of, an optical system of the ER system. In some embodiments, an eye-tracking mechanism within an ER system may adjust which pixels are configured for emission and which for transmission, such as when a different user wears the ER system, or to track a current user's eye movement during display.

FIG. 9A illustrates an embodiment of a layout of a section 900 of a pixel array of dual function pixels. A pixel array of dual function pixels may have one or more subsections that include one or more such pixels configured for emission, and one more pixels configured to receive light. The pixel array may also have various pixels disabled neither to receive nor transmit light. In the section 900 shown are two 3-by-3 subarrays of pixels, the upper right 3-by-3 section 902a and the lower left 3-by-3 subsection 902b. The two subsections 902a and 902b may be separated by one or more rows of disabled pixels, such as the two rows 903a and 903b. Further, the two subsections 902a and 902b may be offset with respect to columns or rows. The subsections 902a and 902b contain a respective pixel configured as a light transmitter, 904a and 904b, in the center of the 3-by-3 subsection, and a respective surrounding periphery 906a and 906b of pixels configured as light receivers. In other embodiments, other configurations of subsections configured with both light receiving and transmitting pixels may be used.

FIG. 9B illustrates a configuration 910 of a pixel array 912 of dual function pixels with two pixels configured as light emitters producing respective emitted light 911a and 911b. In some embodiments, the emitted lights 911a and 911b may be frequency modulated, continuous wave (FMCW) emissions. The emitted lights 911a and 911b may be transmitted to the optical system 914 that includes a focusing lens 915, a light splitting prism or mirror 916, and a reflector 917. Some the emitted light 911a and 911b may pass directly through the splitting prism 916 from the optical system 914 along an sensing path 918 to an object 920, such as a user's head, from which they reflect back along the sensing path. Other amounts of the emitted light 911 and 911b may be directed toward the reflector 917, from which they are reflected back through the splitting prism 916. Interference between the reflections from the object 920 and the reflector 917 may allow for motion or distance detection, such as of a user's eyes.

FIG. 9C illustrates an alternative configuration 930 of a pixel array 932 with two pixels configured as light emitters and producing respective emitted light 931a and 931b. In some embodiments, the emitted lights 931a and 931b may be frequency modulated, continuous wave (FMCW) emissions. The emitted lights 931a and 931b may be transmitted to the optical system 934 that may include a focusing lens 935 and a partially reflecting, optically flat light splitter 936. Some the emitted light 931a and 931b may pass directly through the partially reflecting, optically flat light splitter 936 from the optical system 932 along an sensing path 938 to an object 940, such as a user's head, from which they reflect back along the sensing path 938. Other amounts of the emitted light 931 and 931b may be reflected back from the partially reflecting, optically flat light splitter 936. Interference between the reflections from the object 940 and the partially reflecting, optically flat light splitter 936 may allow for motion or distance detection, such as of a user's eyes.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. A programmable active optical sensor, comprising:
an array of pixels formed in a common set of epitaxial layers, each pixel in the array of pixels including:
a respective vertical cavity surface-emitting laser (VCSEL) diode; and
a respective photodiode (PD); and
a controller electrically connected to each respective VCSEL diode and each respective PD; wherein:
the controller is operable to apply a first electrical bias at a first time to configure a first pixel as a light transmitter only, and to apply a second electrical bias at a second time to configure the first pixel as a light receiver only.

2. The programmable active optical sensor of claim 1, wherein:
the PD of the first pixel is formed in a first subset of epitaxial layers of the common set of epitaxial layers adjacent to a light input-output (LIO) layer of the programmable active optical sensor; and
the VCSEL diode of the first pixel is formed in a second subset of epitaxial layers of the common set of epitaxial layers opposite to the LIO layer of the programmable active optical sensor.

3. The programmable active optical sensor of claim 2, wherein:
the first subset of epitaxial layers includes:
a first p++ type contact layer proximate to the LIO layer;
a first p-type distributed Bragg reflector (DBR) structure adjacent to the first p++ type contact layer and opposite to the LIO layer;
a PD absorption layer adjacent to the first p-type DBR structure and opposite to the p++ type contact layer; and
a first n-type DBR structure adjacent to the PD absorption layer and opposite to the first p-type DBR structure;
the second subset of epitaxial layers includes:
a second n-type DBR structure adjacent to the first n-type DBR structure and opposite to the PD absorption layer;
a quantum wells layer adjacent to the second n-type DBR structure and opposite to the first n-type DBR structure;
a second p-type DBR structure adjacent to the quantum wells layer and opposite to the second n-type DBR structure; and
a second p++ type contact layer adjacent to the second p-type DBR structure and opposite to the quantum wells layer; and
an n-type intra-cavity contact layer is interposed between the first n-type DBR structure and the second n-type DBR structure.

4. The programmable active optical sensor of claim 3, wherein:
the first electrical bias applied by the controller includes:
a ground voltage applied concurrently to the first p++ type contact layer and the n-type intra-cavity contact layer; and
a positive voltage applied to the second p++ type contact layer; and
the second electrical bias applied by the controller includes:
the ground voltage applied concurrently to the n-type intra-cavity contact layer and the second p++ type contact layer; and
a negative voltage to the first p++ type contact layer.

5. The programmable active optical sensor of claim 3, wherein:
the first subset of epitaxial layers includes:
a first n-type contact layer proximate to the LIO layer;
a first n-type distributed Bragg reflector (DBR) structure adjacent to the first n-type contact layer and opposite to the LIO layer;
a PD absorption layer adjacent to the first n-type DBR structure and opposite to the first n-type contact layer; and
a first p-type DBR structure adjacent to the PD absorption layer and opposite to the first n-type DBR structure;
the second subset of epitaxial layers includes:
a second p-type DBR structure adjacent to the first p-type DBR structure and opposite to the PD absorption layer;
a quantum wells layer adjacent to the second p-type DBR structure and opposite to the first p-type DBR structure;
a second n-type DBR structure adjacent to the quantum wells layer and opposite to the second p-type DBR structure; and
a second n-type contact layer adjacent to the second n-type DBR structure and opposite to the quantum wells layer; and
a p++ type intra-cavity contact layer is interposed between the first p-type DBR structure and the second p-type DBR structure.

6. The programmable active optical sensor of claim 1, wherein the pixels are electrically separated by insulating material deposited into regions etched into the common set of epitaxial layers.

7. The programmable active optical sensor of claim 1, wherein the controller is operable to:
apply the first electrical bias to a first subset of pixels of the array of pixels at the first time;
apply the second electrical bias to a second subset of pixels of the array of pixels at the first time;
apply the first electrical bias to a third subset of pixels of the array of pixels at the second time; and
apply the second electrical bias to a fourth subset of pixels of the array of pixels at the second time.

8. An electronic device, comprising:
a display component positioned adjacent to a light transmissive surface of the electronic device;
an array of pixels formed in a common set of epitaxial layers, each pixel in the array of pixels including:
a respective vertical cavity surface-emitting laser (VCSEL) diode; and
a respective photodiode (PD); and
a controller operably linked to the respective VCSEL diode and the respective PD of each pixel of the array of pixels; wherein:
the array of pixels is positioned proximate to the display component, opposite to the light transmissive surface;
when a first electrical bias is applied to a first pixel, the respective VCSEL diode of the first pixel is operable to emit light and the respective PD of the first pixel is unbiased;
when a second electrical bias is applied to the first pixel, the respective PD of the first pixel is biased to detect light and the respective VCSEL diode of the first pixel is unbiased; and
the controller is operable to:
determine signal-to-noise ratios (SNRs) of at least some VCSEL diodes and at least some PDs; and
configure different pixels to operate as VCSEL diodes or PDs at least partly in response to the determined SNRs.

9. The electronic device of claim 8, wherein:
respective PDs of each pixel of the array of pixels are formed in a first subset of epitaxial layers of the common set of epitaxial layers;
respective VCSEL diodes of each pixel of the array of pixels are formed in a second subset of epitaxial layers of the common set of epitaxial layers;
the pixels are electrically separated by insulating material deposited into regions etched into the common set of epitaxial layers; and
the first subset of epitaxial layers of the array of pixels is positioned facing the display component.

10. The electronic device of claim 8, wherein the controller is operable to apply a selection process that:
causes the first electrical bias to be applied to the first pixel;
causes the second electrical bias to be applied to a set of pixels neighboring the first pixel; and
selects the first pixel to be configured to emit light when reflections of emitted light from the first pixel and detected at the set of pixels neighboring the pixel meet a criterion.

11. The electronic device of claim 10, wherein the controller is operable to:
cause the first electrical bias to be applied to each pixel of the array of pixels;
cause the second electrical bias to be applied to each pixel of the array of pixels; and
determine a selected subset of pixels of the array of pixels to configure to emit light.

12. The electronic device of claim 11, wherein the controller is further operable to:
adjust the criterion based on a received adjustment signal;
repeat the selection process for each pixel of the array of pixels to determine an updated subset of pixels to configure to emit light.

13. The electronic device of claim 12, wherein the received adjustment signal is based on at least one of:
an elapsed period of time;
a detected impact to the electronic device; or
a user input received by the electronic device.

14. The electronic device of claim 11, wherein the controller is operable to configure those pixels of the array of pixels not in the selected subset of pixels to detect light.

15. The electronic device of claim 14, wherein the controller is operable to:
cause the pixels of the selected subset of pixels to emit light pulses;
determine that reflections of the emitted light pulses from an object exterior to the electronic device are detected by pixels not in the selected subset of pixels; and
determine a distance to the object based on time-of-flight values of the reflections detected by the pixels not in the selected subset of pixels.

16. An electronic device comprising:
a camera;
an array of pixels positioned adjacent to a light transmissive surface of the electronic device; and
a controller;
wherein:
the array of pixels is formed in a common set of epitaxial layers, each pixel in the array of pixels including:
a respective vertical cavity surface-emitting laser (VCSEL) diode; and
a respective photodiode (PD);
the controller is electrically connected to each respective VCSEL diode and each respective PD of each pixel of the array of pixels; and
the controller is operable to apply a first electrical bias at a first time to configure the respective VCSEL diode of a first pixel to emit light, and to apply a second electrical bias at a second time to configure the respective PD of the first pixel to detect light.

17. The electronic device of claim 16, wherein the controller is operable to associate a selected subset of pixels of the array of pixels with a section of a field of view of the camera.

18. The electronic device of claim 17, wherein the controller is operable to configure pixels of the selected subset of pixels as light emitters for depth sensing to an object in the field of view.

19. The electronic device of claim 18, wherein the camera is operable to apply the depth sensing to the object in the field of view for autofocus.

20. The electronic device of claim 17, wherein:
the camera is a first camera;
the selected subset of pixels is a first selected subset of pixels;
the electronic device further comprises a telephoto camera; and
the controller is operable to associate a second selected subset of pixels of the array of pixels with a section of a field of view of the telephoto camera.
